(19) United States
(12) Patent Application Publication
(10) Pub. No.: US 2013/0130480 A1
(43) Pub. Date: May 23, 2013

(54) METHOD FOR MANUFACTURING A SEMICONDUCTOR DEVICE

(71) Applicants: Hai Won Kim, Gyeonggi-do (KR); Sang Ho Woo, Gyeonggi-do (KR); Sung Kill Cho, Gyeonggi-do (KR); Gil Sun Jang, Chungcheognam-do (KR)

(72) Inventors: Hai Won Kim, Gyeonggi-do (KR); Sang Ho Woo, Gyeonggi-do (KR); Sung Kill Cho, Gyeonggi-do (KR); Gil Sun Jang, Chungcheognam-do (KR)

(73) Assignee: Eugene Technology Co., Ltd., Gyeonggi-do (KR)

(21) Appl. No.: 13/813,978

(22) PCT Filed: Sep. 1, 2011
(86) PCT No.: PCT/KR2011/006485

§ 371 Date: Feb. 4, 2013

(30) Foreign Application Priority Data
Sep. 6, 2010 (KR) 10-2010-0086964

(51) Int. Cl. H01L 21/02

(52) U.S. Cl. CPC H01L 21/02507
USPC 438/479

(57) ABSTRACT

Disclosed is a method for manufacturing a semiconductor device having a multilayer structure. The method for manufacturing a semiconductor device according to the present invention comprises the loading of a substrate into the chamber of a chemical vapor deposition apparatus and the forming of a multilayer structure in which a plurality of doped amorphous silicon layers and a plurality of insulation layers are alternately stacked. Said layers are stacked by alternately and repetitively forming the doped amorphous silicon layer on the substrate by supplying a conductive dopant and silicon precursor into the chamber where the substrate is loaded, and forming the insulation layer containing silicon on the substrate by introducing the silicon precursor and a reaction gas into the chamber where the substrate is loaded.

### TECHNICAL FIELD

The present invention disclosed herein relates to a method for manufacturing a semiconductor device, and more particularly, to a method for manufacturing a semiconductor device having a multilayer structure.

### BACKGROUND ART

Recently, with the advance of semiconductor industries and the requirements of users, electronic equipment is being more highly integrated and has high performance, and thus, semiconductor devices that are the main components of the electronic equipment are also required to be highly integrated and have high performance. However, it is difficult to realize a fine structure for highly integrating semiconductor devices.

For example, to realize the fine structure, a semiconductor manufacturing apparatus having high resolution is required. However, the semiconductor manufacturing apparatus is excessively expensive, and thus is uneconomical or does not fill the needs of markets. Also, as semiconductor devices are becoming more miniaturized, semiconductor manufacturing technologies reach the physical limit.

### DISCLOSURE OF THE INVENTION

### Technical Problem

The present invention provides a method for manufacturing a highly integrated semiconductor device. The present invention also provides a method for manufacturing a semiconductor device having a multilayer structure.

Further another object of the present invention will become evident with reference to following detailed descriptions and accompanying drawings.

### Technical Solution

Embodiments of the present invention provide methods for manufacturing a semiconductor device, the method including: loading a substrate into a chamber of a chemical vapor deposition apparatus; alternately and repetitively forming a doped amorphous silicon layer on the substrate by supplying a silicon precursor and a conductive dopant into the chamber in which the substrate is loaded and forming an insulation layer containing silicon by supplying a silicon precursor and a reaction gas into the chamber in which the substrate is loaded to form a multilayer structure in which a plurality of doped amorphous silicon layers and a plurality of insulation layers are alternately stacked.

In some embodiments, the chemical vapor deposition apparatus may include a low-pressure chemical vapor deposition apparatus.

In other embodiments, the forming of the doped amorphous silicon layer and the forming of the insulation layer may be performed while the substrate is maintained at a constant temperature.

In still other embodiments, the forming of the doped amorphous silicon layer and the forming of the insulation layer may be performed while the substrate is maintained at a temperature of about 500° C. to about 650° C.

In even other embodiments, the forming of the doped amorphous silicon layer and the forming of the insulation layer may be performed while an internal pressure of the chamber is constantly maintained.

In yet other embodiments, the forming of the doped amorphous silicon layer and the forming of the insulation layer may be performed while the internal pressure of the chamber is maintained at a pressure of about 10 Torr to about 300 Torr.

In further embodiments, the doped amorphous silicon layer may have p-type conductivity.

In still further embodiments, the conductive dopant may include a B₂H₆ or BCl₃ gas.

In even further embodiments, the insulation layer containing the silicon may include a silicon oxide layer or a silicon nitride layer.

In yet further embodiments, the forming of the multilayer structure may be performed while the plurality of doped amorphous silicon layers stacked on the multilayer structure are maintained in an amorphous state.

In much further embodiments, the silicon precursor may include at least one gas selected from the group consisting of SiH₄, Si₂H₆, Si₃H₈, and Si₄H₁₀.

In still much further embodiments, the multilayer structure may include n doped amorphous silicon layers and n−1 insulation layers (where n is 2 or more positive integer), and each of the insulation layers may be disposed between the respective n doped amorphous silicon layers.

In even much further embodiments, the multilayer structure may include m insulation layers and m−1 doped amorphous silicon layers (where m is 2 or more positive integer), and each of the doped amorphous silicon layers may be disposed between the respective m insulation layers.

### Advantageous Effects

In the method for manufacturing the semiconductor device according to an embodiment of the present invention, even though the stacked height increases, the multilayer structure may have a constant thickness. Specifically, even though the stacked height increases, the warpage may not occur, and also, the multilayer structure may not decrease in thickness.

Also, since at least two kinds of layers constituting the multilayer structure is formed under the same temperature and pressure within the chamber of the same process apparatus, the process time and cost may be reduced.

Since the multilayer structure is formed to manufacture the semiconductor device including the three-dimensional memory cells, each of the memory cells may have available characteristics regardless of the stacked height. Thus, the more highly integrated semiconductor device may be provided using the same process equipment.

### BRIEF DESCRIPTION OF THE DRAWINGS

FIG. 1 is a flowchart illustrating a method of manufacturing a semiconductor device having a multilayer structure according to a first embodiment of the present invention.

FIG. 2 is a flowchart illustrating a method of manufacturing a semiconductor device having a multilayer structure according to a second embodiment of the present invention.

FIG. 3 is a flowchart illustrating a method of manufacturing a semiconductor device having a modified multilayer structure according to the first embodiment of the present invention.

FIG. 4 is a flowchart illustrating a method of manufacturing a semiconductor device having a modified multilayer structure according to the second embodiment of the present invention.

FIG. 5 is a schematic cross-sectional view of a semiconductor manufacturing apparatus for manufacturing a semiconductor device having a multilayer structure according to embodiments of the present invention.

FIG. 6 is a cross-sectional view of the semiconductor device having the multilayer structure according to the first embodiment of the present invention.

FIG. 7 is a cross-sectional view of the semiconductor device having the multilayer structure according to the second embodiment of the present invention.

FIG. 8 is a cross-sectional view of the semiconductor device having the modified multilayer structure according to the first embodiment of the present invention.

FIG. 9 is a cross-sectional view of the semiconductor device having the modified multilayer structure according to the second embodiment of the present invention.

FIG. 10 is a view of transmission electron microscope photographs for comparing a cross section of a multilayer structure according to embodiments of the prevent invention with a cross section of a comparison sample.

FIG. 11 is a cross-sectional view illustrating an arrangement structure of a semiconductor device having a multilayer structure according to embodiments of the present invention.

### MODE FOR CARRYING OUT THE INVENTION

Hereinafter, embodiments of the present invention will be described in more detail with reference to the accompanying drawings. However, embodiments of the present invention may be modified in various forms, and the scope and spirit of the present invention should not be construed as being limited by the below-described embodiments. These embodiments are provided so that this disclosure will be thorough and complete, and will fully convey the scope of the present invention to those skilled in the art. In the accompanying drawings, like reference numeral refers to like element. Furthermore, various elements and regions in the accompanying drawings are schematically illustrated. Therefore, the present invention is not limited by relative sizes or intervals illustrated in the accompanying drawings.

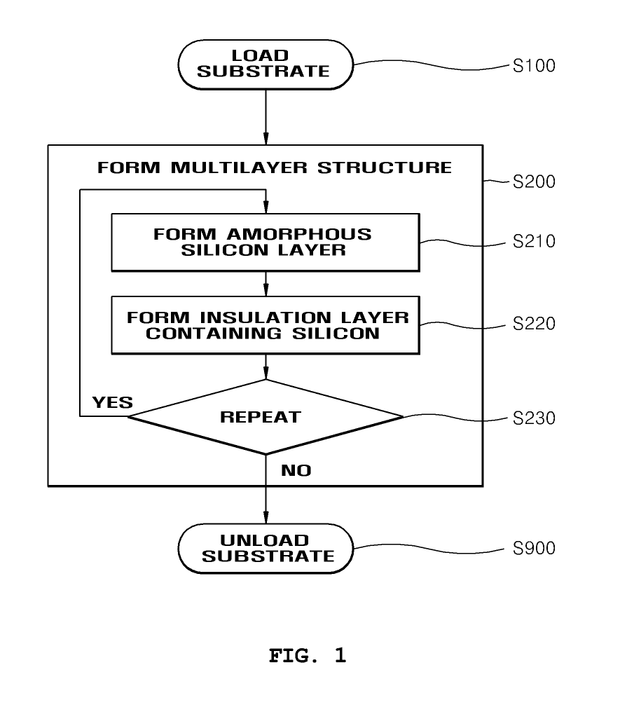

FIG. 1 is a flowchart illustrating a method of manufacturing a semiconductor device having a multilayer structure according to a first embodiment of the present invention.

Referring to FIG. 1, a substrate is loaded into a chamber of a chemical vapor deposition (CVD) apparatus (S100). A multilayer structure may be formed on the substrate loaded into the chamber (S200). To form the multilayer structure, a process of forming an amorphous silicon layer (S210) and a process of forming an insulation layer containing silicon (S220) may be performed together with each other.

The amorphous silicon layer may be formed of doped conductive amorphous silicon. To form the amorphous silicon layer, a silicon-based gas that is a source gas may be used as a silicon precursor. Also, to form the amorphous silicon layer formed of the doped conductive amorphous silicon, a conductive dopant may be supplied together.

The insulation layer containing the silicon may be formed of silicon oxide or silicon nitride. To form the insulation layer containing the silicon and formed of the silicon oxide or silicon nitride, a reaction gas including oxygen or nitrogen together with the silicon precursor may be used as a source gas.

The process of forming the amorphous silicon layer (S210) and the process of forming the insulation layer containing the silicon (S220) may be repetitively performed (S230) in consideration of the number of layers of the multilayer structure to be formed. The process of forming the multilayer structure (S200) by repetitively performing the process of forming the amorphous silicon layer (S210) and the process of forming the insulation layer containing the silicon (S220) may be performed to allow the amorphous silicon layers to be maintained in an amorphous state.

After the multilayer structure is formed, the substrate may be unloaded from the inside of the chamber of the CVD apparatus (S900).

Thus, the multilayer structure may have a structure in which the amorphous silicon layer and the insulation layer containing the silicon are alternately stacked.

The CVD apparatus may be a low-pressure CVD (LPCVD) apparatus. The multilayer structure may be formed while constantly maintaining an internal pressure of the chamber of the LPCVD apparatus. For example, the multilayer structure may be formed while maintaining the inside of the chamber at a pressure of about 10 Torr to about 300 Torr. That is, the process of forming the amorphous silicon layer (S210) and the process of forming the insulation layer containing the silicon (S220) may be performed while constantly maintaining the internal pressure of the chamber.

Also, the multilayer structure may be formed while constantly maintaining a temperature of the substrate within the chamber of the LPCVD apparatus. For example, the multilayer structure may be formed while maintaining the substrate at a temperature of about 500° C. to about 650° C. That is, the process of forming the amorphous silicon layer (S210) and the process of forming the insulation layer containing the silicon (S220) may be performed while constantly maintaining a temperature of the substrate.

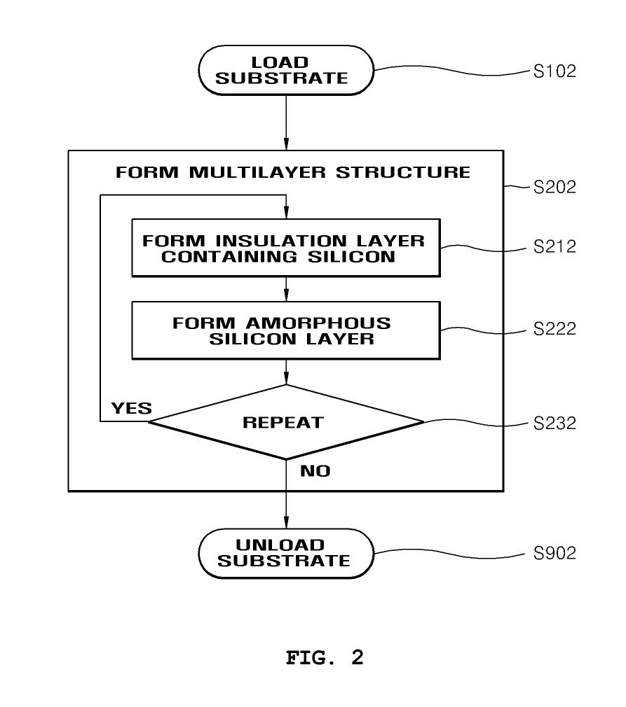

FIG. 2 is a flowchart illustrating a method of manufacturing a semiconductor device having a multilayer structure according to a second embodiment of the present invention.

Referring to FIG. 2, a substrate is loaded into a chamber of a chemical vapor deposition (CVD) apparatus (S102). A multilayer structure may be formed on the substrate loaded into the chamber (S202). Here, a process of forming an insulation layer containing silicon (S212) and a process of forming an amorphous silicon layer (S222) may be performed together with each other to form the multilayer structure.

To form the multilayer structure, the process of forming the insulation layer containing the silicon (S212) and the process of forming the amorphous silicon layer (S222) may be repetitively performed (S232) in consideration of the number of layers of the multilayer structure to be formed. After the multilayer structure is formed, the substrate may be unloaded from the inside of the chamber of the CVD apparatus (S902).

Thus, the multilayer structure may have a structure in which the insulation layer containing the silicon and the amorphous silicon layer are alternately stacked.

That is, the semiconductor device according to the second embodiment of the present invention has the multilayer structure in which the insulation layer containing the silicon and the amorphous silicon layer are alternately stacked as shown in FIG. 2. On the other hand, the semiconductor device according to the first embodiment of the present invention has the multilayer structure in which the amorphous silicon layer and the insulation layer containing the silicon are alternately stacked as shown in FIG. 1.

The CVD apparatus may be a low-pressure CVD (LPCVD) apparatus. The process of forming the insulation layer containing the silicon (S212) and the process of forming the amorphous silicon layer (S222) may be performed while constantly maintaining an internal pressure of the chamber.

Also, the process of forming the insulation layer containing the silicon (S212) and the process of forming the amorphous silicon layer (S222) may be performed while constantly maintaining a temperature of the substrate.

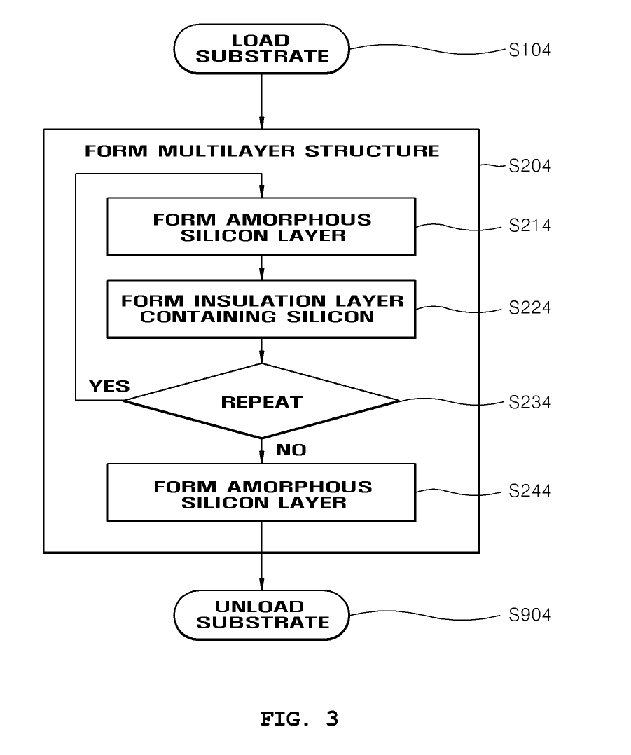

FIG. 3 is a flowchart illustrating a method of manufacturing a semiconductor device having a modified multilayer structure according to the first embodiment of the present invention.

Referring to FIG. 3, a substrate is loaded into a chamber of a chemical vapor deposition (CVD) apparatus (S104). A multilayer structure may be formed on the substrate loaded into the chamber (S204). To form the multilayer structure, a process of forming an amorphous silicon layer (S214) and a process of forming an insulation layer including silicon (S220) may be repetitively performed (S234). Then, a process of additionally forming an amorphous silicon layer may be further performed (S244). After the multilayer structure is formed, the substrate may be unloaded from the inside of the chamber of the CVD apparatus (S904).

Thus, the multilayer structure may have a stacked structure in which the insulation layer containing the silicon is disposed between the amorphous silicon layers.

The CVD apparatus may be a low-pressure CVD (LPCVD) apparatus. That is, the process of forming the amorphous silicon layer (S214), the process of forming the insulation layer containing the silicon (S224), and the process of additionally forming the amorphous silicon layer (S244) may be performed while constantly maintaining the internal pressure of the chamber.

Also, the process of forming the amorphous silicon layer (S214), the process of forming the insulation layer containing the silicon (S224), and the process of additionally forming the amorphous silicon layer (S244) may be performed while constantly maintaining a temperature of the substrate.

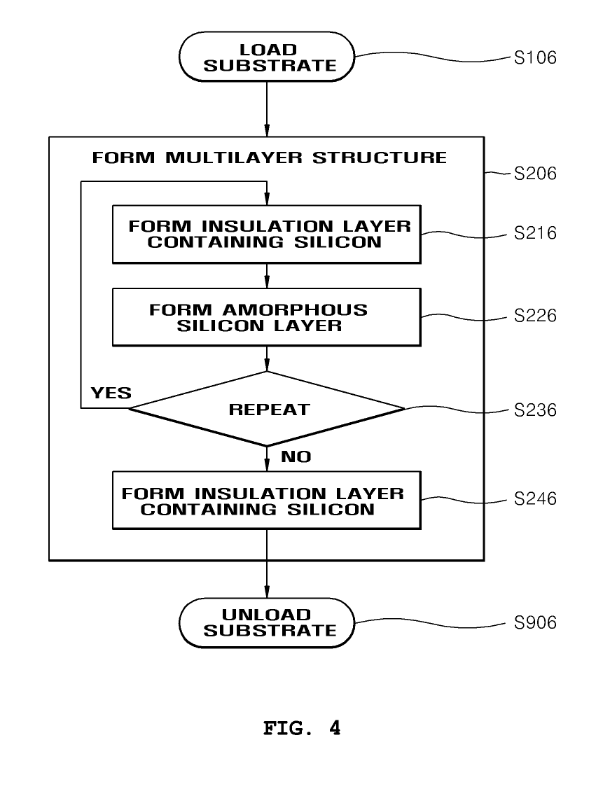

FIG. 4 is a flowchart illustrating a method of manufacturing a semiconductor device having a modified multilayer structure according to the second embodiment of the present invention.

Referring to FIG. 4, a substrate is loaded into a chamber of a chemical vapor deposition (CVD) apparatus (S106). A multilayer structure may be formed on the substrate loaded into the chamber (S206). To form the multilayer structure, a process of forming an insulation layer including silicon (S216) and a process of forming an amorphous silicon layer (S226) may be repetitively performed (S236). Then, a process of additionally forming an insulation layer containing silicon may be further performed (S246). After the multilayer structure is formed, the substrate may be unloaded from the inside of the chamber of the CVD apparatus (S906).

Thus, the multilayer structure may have a stacked structure in which the amorphous silicon layer is disposed between the insulation layers containing the silicon.

The CVD apparatus may be a low-pressure CVD (LPCVD) apparatus. The process of forming the insulation layer containing the silicon (S216), the process of forming the amorphous silicon layer (S226), and the process of additionally forming the insulation layer containing the silicon (S246) may be performed while constantly maintaining an internal pressure of the chamber.

Also, the process of forming the insulation layer containing the silicon (S216), the process of forming the amorphous silicon layer (S226), and the process of additionally forming the insulation layer containing the silicon (S246) may be performed while constantly maintaining a temperature of the substrate.

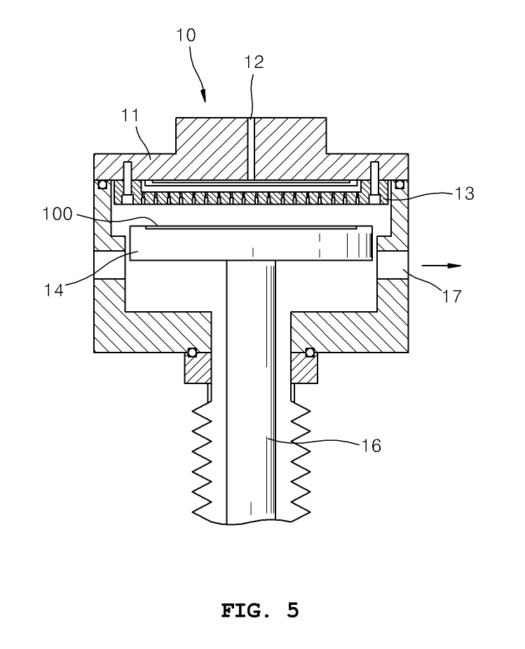

FIG. 5 is a schematic cross-sectional view of a semiconductor manufacturing apparatus for manufacturing a semiconductor device having a multilayer structure according to embodiments of the present invention.

Referring to FIG. 5, an introduction part 12 for introducing a reaction gas is disposed in a chamber 11 of a semiconductor manufacturing apparatus 10. The reaction gas introduced through the introduction part 12 may be sprayed into the chamber 11 through a showerhead 13.

A substrate 100 this is a subject for depositing is placed on a chuck 14. The chuck 14 is supported by a chuck support 16. If necessary, the chuck 14 may be configured to apply heat into the substrate 100 to heat the substrate 100 at a predetermined temperature. After the deposition process is performed by using the above-described units, the reaction gas is discharged through a discharge part 17.

The multilayer structure described with reference to FIGS. 1 to 4 may be manufactured within the semiconductor manufacturing apparatus 10. That is, in the state where the substrate 100 is loaded into the chamber 11 of the semiconductor manufacturing apparatus 10, the processes of forming the amorphous silicon layer (S210, S222, S214, S244, and S226) and the processes of forming the insulation layer containing the silicon (S220, S212, S224, S216, and S246) may be performed together with each other.

Here, an internal pressure of the chamber 11 may be constantly maintained. Also, the chuck 14 may apply heat into the substrate 100 to constantly maintain a temperature of the substrate 100.

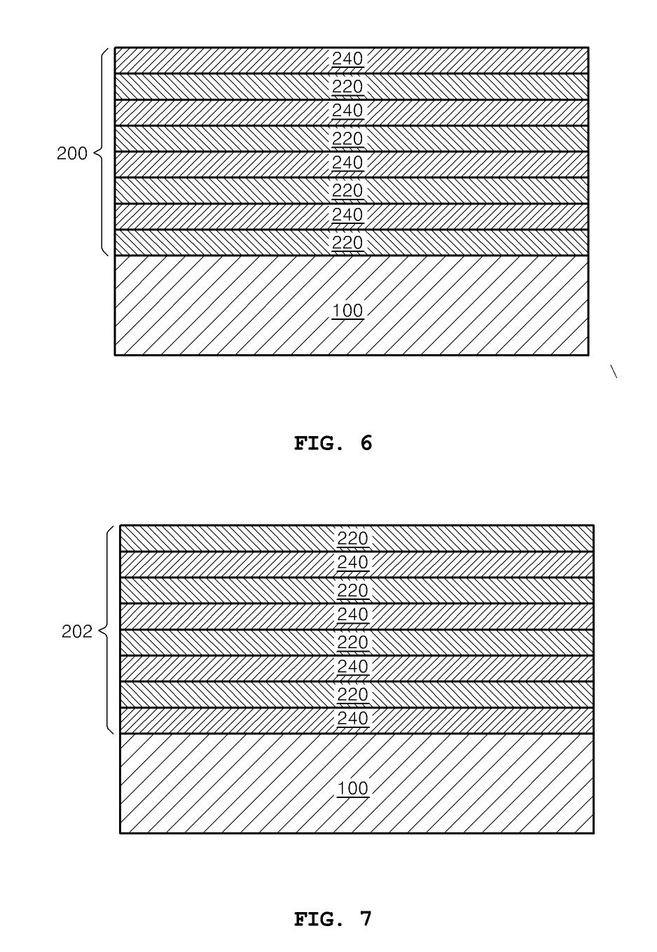

FIG. 6 is a cross-sectional view of the semiconductor device having the multilayer structure according to the first embodiment of the present invention. Specifically, FIG. 6 illustrates a multilayer structure formed through the method of manufacturing the semiconductor device having the multilayer structure according to the first embodiment of the present invention as shown in FIG. 1.

Referring to FIG. 6, a multilayer structure 200 may be disposed on a substrate 100. The multilayer structure 200 may be a structure in which an amorphous silicon layer 220 and an insulation layer 240 containing silicon are alternately stacked. That is, the multilayer structure 200 may be a structure in which amorphous silicon layers 220 and insulation layers 240 containing silicon, which have the same number, are alternately stacked.

For example, the substrate 100 may include a semiconductor substrate such as a silicon or compound semiconductor wafer. Alternatively, the substrate 100 may be formed of a substrate material different from semiconductors such as glass, metal, ceramic, quartz, and the like.

The form the amorphous silicon layer 220, a silicon precursor that is a silicon-based gas may be used as a source gas. The silicon-based gas may include SiH₄, Si₂H₆, Si₃H₈, or Si₄H₁₀.

The amorphous silicon layer 220 may be formed of doped conductive amorphous silicon. To form the doped conductive amorphous silicon, a conductive dopant may be supplied together. The conductive type may be a p-type. Also, the conductive dopant may be a B₂H₆ or BCl₃ gas.

The insulation layer 240 containing the silicon may be formed of silicon oxide or silicon nitride. To form the insulation layer 240 containing the silicon, a silicon precursor and a reaction gas including oxygen or nitrogen may be used together. The reaction gas may be, for example, an N₂O gas.

FIG. 7 is a cross-sectional view of the semiconductor device having the multilayer structure according to the second embodiment of the present invention. Specifically, FIG. 7 illustrates a multilayer structure formed through the method of manufacturing the semiconductor device having the multilayer structure according to the second embodiment of the present invention as shown in FIG. 2.

Referring to FIG. 7, a multilayer structure 202 may be disposed on a substrate 100. The multilayer structure 202 may have a structure in which an insulation layer 240 containing silicon and an amorphous silicon layer 220 are alternately stacked. That is, the multilayer structure 202 may be a structure in which insulation layers 240 containing silicon and amorphous silicon layers 220, which have the same number, are alternately stacked.

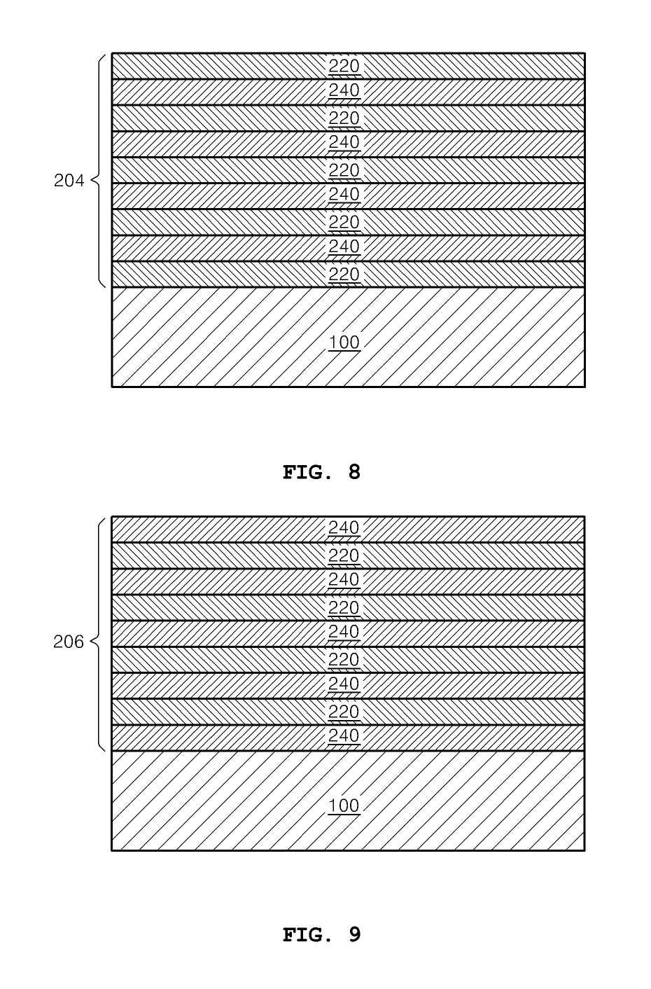

FIG. 8 is a cross-sectional view of the semiconductor device having the modified multilayer structure according to the first embodiment of the present invention. Specifically, FIG. 8 illustrates a multilayer structure formed through the method of manufacturing the semiconductor device having the modified multilayer structure according to the first embodiment of the present invention as shown in FIG. 3.

Referring to FIG. 8, a multilayer structure 204 may be disposed on a substrate 100. The multilayer structure 204 may have a structure in which a plurality of amorphous silicon layers 220 are stacked with a silicon-containing insulation layer 240 therebetween.

That is, the multilayer structure 204 may include n silicon-containing amorphous silicon layers 220 and n−1 silicon-containing insulation layers 240. Also, the respective n amorphous silicon layers 220 may be stacked with the silicon-containing insulation layer 240 therebetween (where n is 2 or more positive integer).

FIG. 9 is a cross-sectional view of the semiconductor device having the modified multilayer structure according to the second embodiment of the present invention. Specifically, FIG. 9 illustrates a multilayer structure formed through the method of manufacturing the semiconductor device having the modified multilayer structure according to the second embodiment of the present invention as shown in FIG. 4.

Referring to FIG. 9, a multilayer structure 206 may be disposed on a substrate 100. The multilayer structure 206 may have a structure in which a plurality of silicon-containing insulation layers 240 are staked with each of amorphous silicon layers 220 therebetween.

That is, the multilayer structure 206 may include m silicon-containing insulation layers 240 and m−1 amorphous silicon layers 240. Also, the respective m amorphous silicon layers 220 may be stacked with the silicon-containing insulation layer 240 therebetween (where m is 2 or more positive integer).

The multilayer structures 200, 202, 204, and 206 according to the embodiments of the present invention are disclosed with reference to FIGS. 6 to 9. However, the present invention is not limited to.

Although each of the disclosed multilayer structures 200, 202, 204, and 206 according to the embodiments of the present invention has a structure in which two kinds of thin films are alternately stacked, at least three kinds of thin films may be stacked within the technical concept of the prevent invention.

For example, three kinds of layers such as an amorphous silicon layer, a silicon oxide layer, and a silicon nitride layer may be alternately stacked. Alternatively, a silicon oxide layer and a silicon nitride layer may be alternately disposed between amorphous silicon layers.

Also, three kinds of layers such as an n-type amorphous silicon layer, a p-type amorphous silicon layer, and a silicon insulation layer may be alternately stacked. Alternatively, an n-type amorphous silicon layer, a p-type amorphous silicon layer, a silicon oxide layer, and a silicon nitride layer may be alternately stacked or disposed as occasion demands.

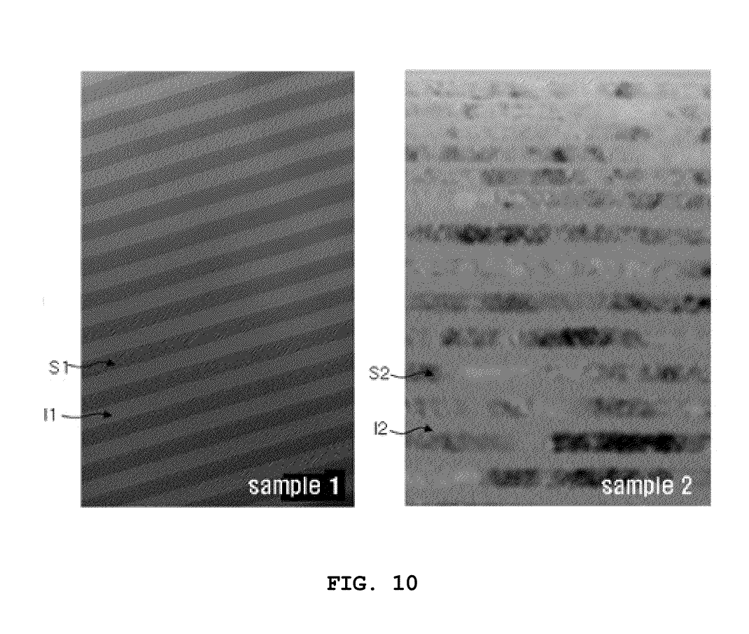

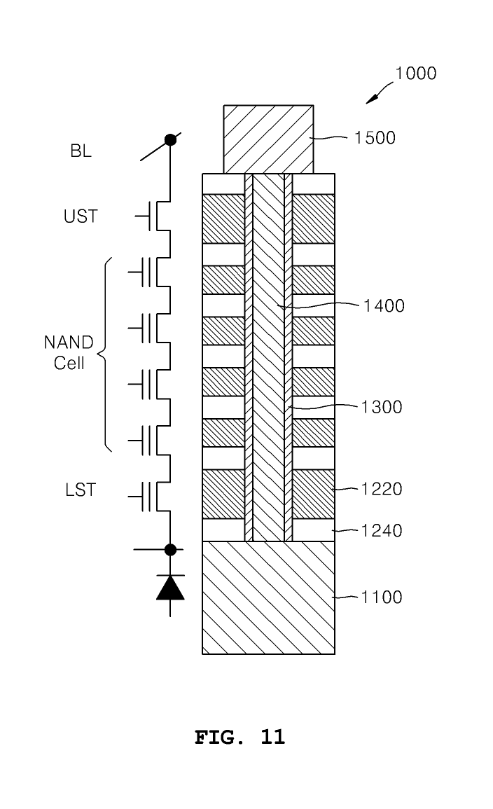

FIG. 10 is a view of transmission electron microscope photographs for comparing a cross section (a sample 1) of a multilayer structure according to embodiments of the prevent invention with a cross section (a sample 2) of a comparison sample.

Referring to FIG. 10, cross sections of a multilayer structure (a sample 1) according to embodiments of the present invention and a comparison sample (a sample 2) may be compared with each other by using transmission electron microscope photographs.

Specifically, the multilayer structure (the sample 1) according to the embodiments of the present invention has a multilayer structure in which a p-type doped amorphous silicon layer S1 and a silicon oxide layer I1 are alternately stacked. Also, the comparison sample (the sample 2) has a multilayer structure in which a polysilicon layer S2 and a silicon oxide layer I2 are alternately stacked.

In the multilayer structure (the sample 1) according to the embodiments of the present invention, each of the amorphous silicon layer S1 and the silicon oxide layer I1 may have a predetermined thickness. Particularly, the silicon oxide layer I1 may have a predetermined thickness regardless of a stacked height.

Here, the predetermined thickness is not limited to means in which the amorphous silicon layer S1 and the silicon oxide layer I1 have the same thickness. That is, the meaning that each of the amorphous silicon layer S1 and the silicon oxide layer I1 has a predetermined thickness represents that the amorphous silicon layer S1 and the silicon oxide layer I1 have substantially the same thickness under the same conditions (for example, an internal pressure of a chamber, a temperature of a substrate, and a flow rate of a source or reaction gas) when a process time is the same.

Of cause, although a thickness of the amorphous silicon layer S1 or the silicon oxide layer I1 doe not gradually increase in direct proportion to a process time, the amorphous silicon layer S1 or the silicon oxide layer I1 may have a thickness gradually increasing as the process time elapses.

Thus, with this point in view, an individual layer of the multilayer structure constituted by the amorphous silicon layer S1 or the silicon oxide layer I1 may vary as occasion demands.

However, it is seen that each of the polysilicon layer S2 and the silicon oxide layer I2 does not have a predetermined thickness in the comparison sample (the sample 2). Particularly, the silicon oxide layer I2 may have a thickness gradually thinner as a stacked height increases.

In the comparison sample (the sample 2), a phenomenon in which the silicon oxide layer I2 has a thickness gradually thinner as a stacked height increases may occur because stress is accumulated due to crystallization of the polysilicon layer S2 as the number of stacked layers increases.

Referring to FIG. 5, if the number of stacked layers increases, warpage of the substrate 10 may occur due to membrane stress to reduce a contact area between the substrate 10 and a chuck 14. Thus, since sufficient heat is not applied into the substrate 10, an individual layer to be formed on the substrate 10 may decrease in thickness. Specifically, if the warpage of the substrate 10 is excessive, it may be difficult to form the individual layer to be formed on the substrate at a desired thickness even though the process time increases.

That is, due to the accumulated membrane stress in the comparison sample (the sample 2), an individual layer of the multilayer structure may decrease in thickness to cause the warpage of the multilayer structure.

However, in the multilayer structure (the sample 1) according to the embodiments of the present invention, since the silicon layer S1 of the multilayer structure is amorphous, the stress due to crystallization of the silicon layer S1 may not occur. Thus, even though the number of stacked layers increases, the silicon oxide layer I1 may not decrease in thickness. Therefore, the warpage of the multilayer structure may not occur.

As a result, the multilayer structure (the sample 1) according to the embodiments of the present invention may be formed so that the amorphous silicon layer S1 of the multilayer structure is maintained in the amorphous state. For this, the multilayer structure (the sample 1) according to the embodiments of the present invention may be formed while the substrate 100 is maintained at a relatively low constant temperature of about 500° C. to about 650° C. as described above. Alternatively, the multilayer structure (the sample 1) according to the embodiments of the present invention may be formed while the substrate 100 is maintained at a constant temperature of about 570° C. or less.

Also, the multilayer structure (the sample 1) according to the embodiments of the present invention may be formed while the chamber 11 of the LPCVD apparatus is maintained at a constant internal pressure. In this case, deterioration of surface roughness characteristics of the silicon layer and I-V characteristics of the insulation layer including the silicon which may occur in a case of a plasma CVD apparatus is used may be prevented.

FIG. 11 is a cross-sectional view illustrating an arrangement structure of a semiconductor device having a multilayer structure according to embodiments of the present invention.

Referring to FIG. 11, a semiconductor device 1000 according to embodiments of the present invention may be a non-volatile memory device in which a silicon layer 1220 ad a silicon insulation layer 1240 are alternately stacked to constitute a plurality of NAND flash cells and upper/lower selecting transistor (UST/LST).

The silicon layer 1220 and the silicon insulation layer 1240 may be the amorphous silicon layer 220 and the silicon-containing insulation layer 240 as shown in FIGS. 6 to 9 or resultant layers obtained by thermally treating the amorphous silicon layer 220 and the silicon-containing insulation layer 240, respectively.

The silicon layer 1220 may be, for example, a doped conductive silicon layer. The silicon layer 1220 may be a doped amorphous silicon layer or a doped polysilicon layer. When the silicon layer 1220 is the doped polysilicon layer, the silicon layer 1220 may be in an amorphous state until the multilayer structure is completely formed. Then, the silicon layer 1220 having the amorphous state may be changed into a polycrystalline state through a separate thermal treatment process.

The silicon layer 1220 may be, for example, a p-type doped silicon layer. When the semiconductor device 1000 is the non-volatile memory device including the NAND flash cells, the silicon layer 1220 may have p-type conductivity to improve program/erase characteristics. When the silicon layer 1220 has the p-type conductivity, since a work function is relatively high when compared that the silicon layer 1220 has n-type conductivity, the program/erase characteristics may be improved.

To manufacturing the semiconductor device 1000, a multilayer structure in which the silicon layer 1220 and the silicon insulation layer 1240 are alternately stacked on the substrate 1100 is formed. After a through hole (now shown) passing through the multilayer structure to expose the substrate 1100 is formed, a charge storage layer 1300 is formed on a surface of the through hole. Then, the through hole may be filled to form a semiconductor pillar 1400. The charge storage layer 1300 may include a tunneling oxide layer, a charge trap layer, and a blocking insulation layer. Thereafter, an interconnection layer 1500 electrically connected to the semiconductor pillar 1400 is formed. The interconnection layer 1500 may be a bit line interconnection of the semiconductor device 1000.

The uppermost and lowermost layers of the silicon layer 1220 may be gate electrodes of the UST/LST, respectively. Intermediate layers of the silicon layer 1220 except for the uppermost and lowermost layers may be gate electrodes of the NAND flash cells, respectively.

Thus, if the alternately stacked number of silicon layers 1220 and silicon insulation layers 1240 increases so that the semiconductor device 1000 includes more NAND flash cells, more NAND flash cells may be stacked in a direction perpendicular to the substrate 1100.

To enable each of the NAND flash cells to effectively program or erase data, each of the silicon layer 1220 and the silicon insulation layer 1240 should have a predetermined thickness, particularly, a desired thickness in the direction perpendicular to the substrate 1100 regardless of the stacked height.

When the multilayer structures 200, 202, 204, and 205 according to the embodiments of the present invention are formed, the semiconductor device 1000 may include more NAND flash cells. Thus, the semiconductor device 100 may have available characteristics. Therefore, the semiconductor device 1000 including three-dimensional NAND flash cells may be manufactured.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention may be applied in various types of semiconductor manufacturing processes such as the deposition process.

1. A method for manufacturing a semiconductor device, the method comprising:
loading a substrate into a chamber of a chemical vapor deposition apparatus;
alternately and repetitively forming a doped amorphous silicon layer on the substrate by supplying a silicon precursor and a conductive dopant into the chamber in which the substrate is loaded and forming an insulation layer containing silicon by supplying a silicon precursor and a reaction gas into the chamber in which the substrate is loaded to form a multilayer structure in which a plurality of doped amorphous silicon layers and a plurality of insulation layers are alternately stacked.

2. The method of claim 1, wherein the chemical vapor deposition apparatus is a low-pressure chemical vapor deposition apparatus.

3. The method of claim 1, wherein the forming of the doped amorphous silicon layer and the forming of the insulation layer are performed while the substrate is maintained at a constant temperature.

4. The method of claim 3, wherein the forming of the doped amorphous silicon layer and the forming of the insulation layer are performed while the substrate is maintained at a temperature of about 500° C. to about 650° C.

5. The method of claim 1, wherein the forming of the doped amorphous silicon layer and the forming of the insulation layer are performed while an internal pressure of the chamber is constantly maintained.

6. The method of claim 5, wherein the forming of the doped amorphous silicon layer and the forming of the insulation layer are performed while the internal pressure of the chamber is maintained at a pressure of about 10 Torr to about 300 Torr.

7. The method of claim 1, wherein the doped amorphous silicon layer has p-type conductivity.

8. The method of claim 7, wherein the conductive dopant comprises a B₂H₆ or BCl₃ gas.

9. The method of claim 1, wherein the insulation layer containing the silicon comprises a silicon oxide layer or a silicon nitride layer.

10. The method of claim 1, wherein the forming of the multilayer structure is performed while the plurality of doped amorphous silicon layers stacked on the multilayer structure are maintained in an amorphous state.

11. The method of claim 1, wherein the silicon precursor comprises at least one gas selected from the group consisting of SiH₄, Si₂H₆, Si₃H₈, and Si₄H₁₀.

12. The method of claim 1, wherein the multilayer structure comprises n doped amorphous silicon layers and n−1 insulation layers (where n is 2 or more positive integer), and each of the insulation layers is disposed between the respective n doped amorphous silicon layers.

13. The method of claim 1, wherein the multilayer structure comprises m insulation layers and m−1 doped amorphous silicon layers (where m is 2 or more positive integer), and
each of the doped amorphous silicon layers is disposed between the respective m insulation layers.
